(19) United States
(12) Patent Application Publication
(10) Pub. No.: US 2007/0200211 A1
(43) Pub. Date: Aug. 30, 2007

(54) Multilayer wiring substrate and method of connecting the same

(75) Inventors: Tsuyoshi Kobayashi, Nagano (JP); Shigetsugu Muramatsu, Nagano (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd.

(21) Appl. No.: 11/705,402

(22) Filed: Feb. 13, 2007

(30) Foreign Application Priority Data
Feb. 15, 2006 (JP) P2006-038202

(51) Int. Cl. H01L 23/495

(52) U.S. Cl. 257/676

(57) ABSTRACT

In the case in which an electrical connection between upper and lower layers is to be carried out through a via opening portion 16 provided on an insulating layer 14 of a wiring substrate constituting a multilayer wiring substrate, the electrical connection between the upper and lower layers is performed through a conductive material 30 while exposing a part of wall surfaces of the via opening portion 16 of the insulating layer without covering all of the wall surfaces of the via opening portion 16 with the conductive material 30.

This application claims priority to Japanese Patent Application No. 2006-038202, filed Feb. 15, 2006, in the Japanese Patent Office. The priority application is incorporated by reference in its entirety.

### TECHNICAL FIELD

The present disclosure relates to a multilayer wiring substrate and a method of connecting the multilayer wiring substrate. More particularly, the present disclosure relates to a multilayer wiring substrate and a method of connecting the multilayer wiring substrate in which an electrical connecting method between a wiring layer to be an upper layer and a wiring layer to be a lower layer among respective insulating layers of a wiring substrate constituting the multilayer wiring substrate is improved.

### RELATED ART

In related art, an electrical connecting method between layers of respective wiring substrates in a multilayer wiring substrate is executed by forming a via or a through hole on a wiring substrate in a connecting portion to plate the opening portion or filling a conductive paste in the opening portion to maintain an electrical connection between the layers.

In recent years, in a buildup substrate for a high density wiring, a through hole is not formed across a large number of layers but a hole for maintaining an electrical connection corresponding to one layer is usually formed by a laser processing or a technique based on a photoprocess using a photosensitive resin.

In a method of electrically connecting layers of a multilayer wiring substrate according to the related-art art, in a stage for forming an opening portion for the connection, a hole diameter capable of ensuring a mass productivity is approximately 50 μm also in a laser processing or a photoprocess in which micromachining can be carried out much more greatly than drilling. In order to ensure a connecting reliability of an opening hole and a wiring, furthermore, a larger receiving pad than the hole diameter is usually formed. On the other hand, in a wiring forming technique, it is possible to form a fine wiring having a wiring width of 20 μm and a wiring interval of 20 μm under the existing circumstances.

As a result, in order to provide a wiring in the layer, it is necessary to increase and ensure a wiring pitch so as to maintain a via forming portion in a connecting part with an upper layer or a lower layer even if the wiring width is set to be 20 μm and the wring interval is set to be 20 μm. Consequently, the wiring length is increased and the wiring width is increased. Finally, a size of a product is increased. Furthermore, the increase in the wiring length, the increase in the wiring width and a change thereof also influence a transmitting characteristic of an electrical signal. For this reason, a characteristic of a product is deteriorated.

Next, a related-art method of manufacturing a multilayer wiring substrate will be described with reference to the drawings. FIGS. 1A and 1B are sectional and plane views showing an interlayer connecting structure based on a via, and FIG. 2 shows a step of a via interlayer connection based on a semiadditive method using a laser in a hole forming process.

First of all, in FIG. 2A, a lower wiring 12 is formed on a resin substrate 10 to be a lower layer. In this case, in the formation of the lower wiring 12, wiring can be carried out by patterning through a photolithographic step which has been well known. In FIG. 2B, subsequently, an insulating resin layer 14 to be an upper layer is formed on the resin substrate 10 provided with the wiring 12. As shown in FIG. 2C, then, a via opening portion 16 is formed on the insulating resin layer 14 by a laser to expose a part of the wiring 12. The via opening portion 16 is formed like a taper in which a diameter is gradually decreased downward as shown in the drawing.

In FIG. 2D, next, a plating seed layer 18 is formed by copper electoless plating over a whole upper surface of the insulating resin layer 14 including a bottom face of the via opening portion 16 to which a part of the wiring 12 is exposed and a side surface of the via opening portion 16. In FIG. 2E, subsequently, the plating seed layer 18 is coated with a plating resist and predetermined patterning is executed to form a plating resist 20 in such a manner that portions for forming a via connecting portion and a wiring are opened.

In FIG. 2F, then, copper electrolytic plating is carried out by utilizing the plating resist 20. Consequently, the via opening portion 16 is filled with copper by electrolytic plating so that a via 22 for an interlayer connection is formed, and furthermore, a predetermined wiring pattern 24 is formed on the insulating resin layer 14 to be the upper layer. In FIG. 2G, thereafter, the plating resist 20 is removed. In FIG. 2H, furthermore, the plating seed layer 18 present under the plating resist 20 thus removed is removed by etching. Thus, the via connecting structure shown in FIG. 1 is formed. In FIG. 1, 12 denotes a lower wiring, 13 denotes a lower pad to be a part of the lower wiring, 22 denotes a connecting via, 24 denotes an upper wiring, and 25 denotes an upper pad to be a part of the upper wiring. Thus, there is finished a structure in which the lower wiring 12 (the lower pad 13) is electrically connected to the upper wiring 24 (the upper pad 25) through the via 22 for an interlayer connection.

The related art includes Japanese Patent Unexamined Publication No. 2003-218516 Publication (Patent Document 1). According to the art, it has been proposed that in a method of manufacturing a wiring substrate in which a wiring substrate having a wiring pattern formed thereon is covered with an insulating layer, a via hole is formed on the insulating layer and the via hole is plated, a surface having the wiring pattern formed thereon is coated with a resin having an electrical insulating property and the electrical insulating layer is then cured by a heating treatment using an infrared radiation in a process for forming an insulating layer in such a manner that an adhesion of the insulating layer and the wiring pattern can be enhanced and the wiring pattern can be formed at a high density.

According to the related-art method of manufacturing a multilayer wiring substrate, it is necessary to increase a wiring pitch in order to maintain a via forming portion in a connecting part to an upper layer or a lower layer in a connection between the layers. As a result, there is a problem in that a wiring length is increased, a wiring width is increased and a size of a product is increased. Moreover, a transmitting characteristic of an electrical signal of the multilayer wiring substrate is also influenced by the increase in the wiring length, the increase in the wiring width and a change thereof.

The wiring pitch for maintaining the via forming portion in the connection between the layers in the multilayer wiring substrate will be described with reference to FIGS. 3 and 4. In a method of setting a width of the wiring 24, a wiring interval and a diameter of the via pad portion 25 to be 20 μm, 20 μm and 100 μm respectively and arranging a large number of via pad portions 25 shown in FIG. 3 in parallel as in the related-art method as connecting conditions for the wiring 24 and the via pad portion 25, it is necessary to set a pitch of the via pad portion 25 to be 120 μm in order to carry out a connection through the via under the existing circumstances.

Also in the case in which the width of the wiring 24 is set to be 20 μm, the wiring interval is set to be 20 μm and the diameter of the via pad portion 25 is set to be 100 μm, and a large number of via pad portions 25 shown in FIG. 4 are stagger arranged as the connecting conditions, similarly, it is necessary to set the pitch of the via pad portion 25 to be 80 μm in order to carry out the connection through the via under the existing circumstances.

### SUMMARY

Embodiments of the present invention provide a multilayer wiring substrate and a method of connecting the multilayer wiring substrate in which an increase in a wiring pitch and an increase in a wiring length and a wiring width are not required for maintaining a via forming portion and an increase in a size of a product is not required as a result in an electrical connection between layers of each wiring substrate of the multilayer wiring substrate.

According to an aspect of one or more embodiments of the invention, a method of connecting a multilayer wiring substrate comprises the step of carrying out an electrical connection between upper and lower layers through a conductive material while exposing a part of wall surfaces of an opening portion provided on an insulating layer of each wiring substrate constituting the multilayer wiring substrate without covering all of the wall surfaces of the opening portion of the insulating layer with the conductive material when performing the electrical connection between the upper and lower layers through the opening portion.

One or more embodiments of the invention is characterized in that either a wiring layer to be the upper layer and a wiring layer to be the lower layer has a wiring width in a connecting portion which is not greater than a wiring width before and after the connecting portion but is almost equal thereto.

One or more embodiments of the invention is characterized in that a plurality of wiring connecting portions between the upper and lower layers is formed in one opening portion. One or more embodiments of the invention is characterized in that a connecting portion of a wiring layer to be the lower layer is a via filled with a conductive material. Alternatively, the invention is characterized in that a connecting portion of a wiring layer to be the upper layer is a via in which a conductive material is formed on a part of the wall surfaces of the opening portion of the insulating layer.

One or more embodiments of the invention is characterized in that a wiring layer to be the upper layer is electrically connected to a connecting portion of a wiring layer to be the lower layer, and a wiring layer to be a further upper layer is electrically connected to the same connecting portion.

One or more embodiments of the invention is characterized in that the opening portion provided on the insulating layer is inclined to a plane of a connecting portion and an inclination angle is smaller than 90 degrees.

Moreover, according to another aspect of one or more embodiments of the invention, a multilayer wiring substrate has a structure in which an upper wiring layer and a lower wiring layer are electrically connected to each other through an opening portion provided on an insulating layer of each wiring substrate constituting the multilayer wiring substrate and serving to carry out an electrical connection between the upper and lower layers through a conductive material while exposing a part of wall surfaces of the opening portion without covering all of the wall surfaces of the opening portion of the insulating layer with the conductive material.

### BRIEF DESCRIPTION OF THE DRAWINGS

FIG. 1A a sectional view showing an interlayer connecting structure through a via according to a related-art example,

FIG. 1B is a plane view showing an interlayer connecting structure through a via according to a related-art example,

FIGS. 2A to 2H are views showing a related-art step of a via interlayer connection by a semiadditive method,

FIG. 3 is a view showing an example of an array of a large number of via pads,

FIG. 4 is a view showing another example of the array of the large number of via pads,

FIGS. 5A to 5G views showing a step of a via interlayer connection according to the invention,

FIGS. 6A to 6C are views showing an example of a via interlayer connection according to the invention,

FIGS. 7A and 7B are views showing another example of a via interlayer connection according to the invention,

FIGS. 8A to 8C are views showing an interlayer connecting structure of a multilayer wiring substrate according to the related art,

FIGS. 9A and 9B are views showing a first embodiment of an interlayer connecting structure of a multilayer wiring substrate according to the invention,

FIGS. 10A and 10B are views showing another embodiment of the interlayer connecting structure of the multilayer wiring substrate according to the invention,

FIGS. 11A and 11B are views showing a further embodiment of the interlayer connecting structure of the multilayer wiring substrate according to the invention,

FIG. 12 is a view showing an embodiment of an interlayer connecting structure for a plurality of layers according to the invention,

FIG. 13 is a view showing an inclination state of an opening portion,

FIGS. 14A and 14B are views showing a first embodiment of an interlayer connecting structure according to the invention using a filled via,

FIG. 15 is a view showing another embodiment of the interlayer connecting structure according to the invention using the filled via,

FIG. 16 is a view showing a first embodiment of an interlayer connecting structure according to the invention using an unfilled via,

FIG. 17 is a view showing an embodiment of an interlayer connecting structure for a plurality of layers using the filled via,

FIG. 18 is a view showing an embodiment of an interlayer connecting structure for a plurality of layers using a double filled via,

FIGS. 19A and 19B are views showing a first embodiment of an interlayer connecting structure in which an upper wiring is connected rectilinearly,

FIGS. 20A and 20B are views showing another embodiment of the interlayer connecting structure in which the upper wiring is connected rectilinearly,

FIGS. 21A and 21B are views showing a first embodiment of an interlayer connecting structure in which a plurality of wirings is connected,

FIGS. 22A and 22B are views showing another embodiment of the interlayer connecting structure in which the wirings are connected,

FIGS. 23A and 23B are views showing a further embodiment of the interlayer connecting structure in which the wirings are connected,

FIGS. 24A and 24B are views showing a first embodiment of an interlayer connecting structure in which a plurality of wirings is connected to each other, and

FIGS. 25A and 25B are views showing another embodiment of the interlayer connecting structure in which the wirings are connected to each other.

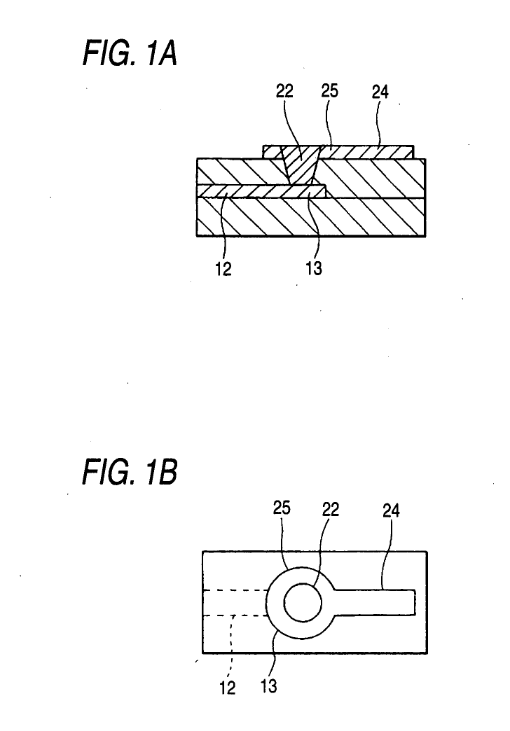

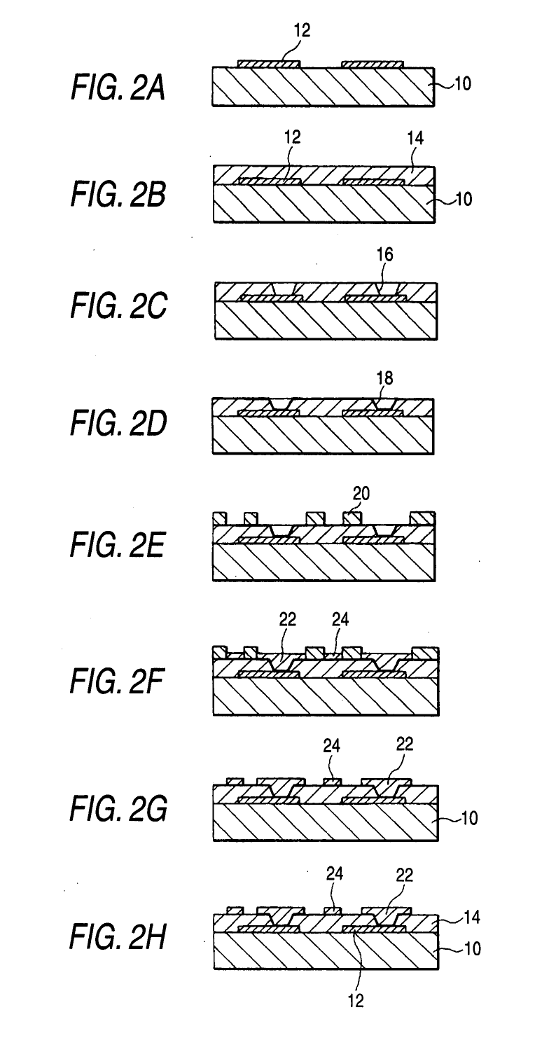

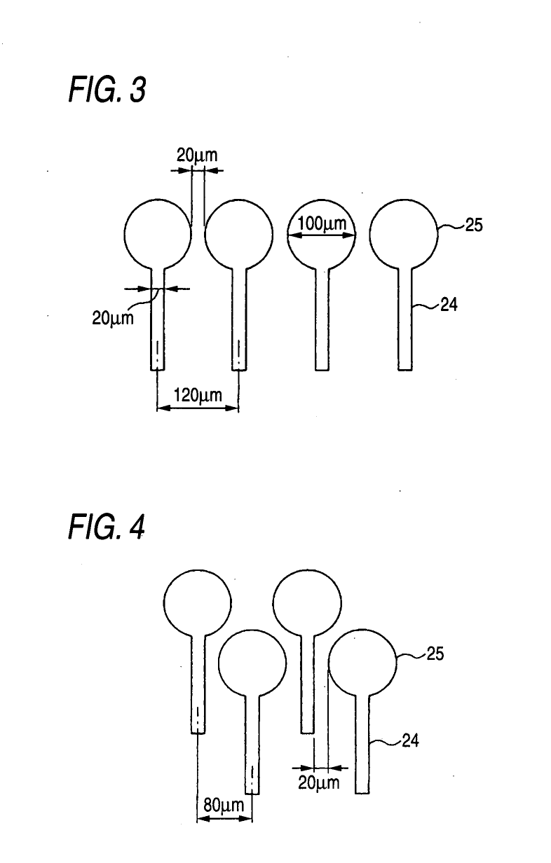

### DETAILED DESCRIPTION

Embodiments of the invention will be described below in detail with reference to the accompanying drawings.

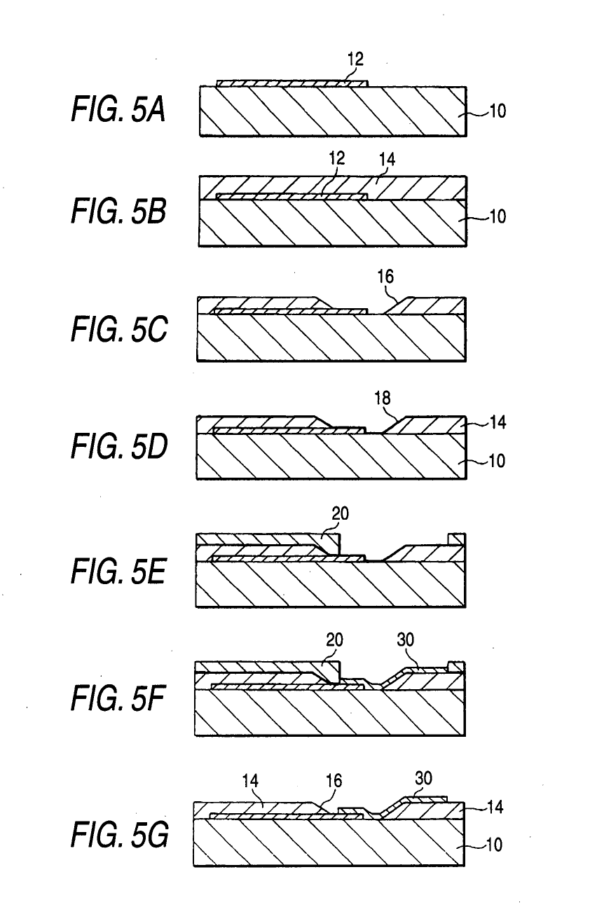

FIG. 5 shows a method of manufacturing a multilayer wiring substrate according to the invention in order of a step.

First of all, in FIG. 5A, a lower wiring 12 is formed on a resin substrate 10 to be a lower layer. In this case, the lower wiring 12 is formed by patterning through a photolithographic step which has been well known. In FIG. 5B, subsequently, an insulating resin layer 14 to be an upper layer is formed on the resin substrate 10 provided with the wiring 12. As shown in FIG. 5C, then, a via opening portion 16 is formed on the insulating resin layer 14 to expose a part of the wiring 12.

The via opening portion 16 is formed like a taper in which a diameter is gradually decreased downward as shown in the drawing and a wall surface of the via opening portion 16 is inclined. It is also possible to form an opening portion of the via opening portion 16 having the inclined portion by setting the insulating resin layer 14 to be a photosensitive resin and carrying out an exposure and development through a photoprocess. It is possible to obtain the via opening portion 16 provided with an inclined wall having an optional angle by carrying out an underexposure in case of a positive photosensitive resin and carrying out an overexposure in case of a negative photosensitive resin.

In addition to the method of forming the via opening portion 16 through the photoprocess, it is also possible to form the opening portion of the via opening portion 16 having a tapered wall surface with an optional angle through a laser processing step. Moreover, it is also possible to form the via opening portion 16 by a stamping press or die embedding. They will be described below.

In FIG. 5D, next, a plating seed layer 18 is formed by copper electoless plating over a whole upper surface of the insulating resin layer 14 including a bottom face of the via opening portion 16 to which a part of the wiring 12 is exposed and a side surface of the via opening portion 16.

In FIG. 5E, subsequently, the plating seed layer 18 is coated with a plating resist and a plating resist 20 having predetermined patterning is formed in such a manner that portions for forming a via connecting portion and a wiring are opened. In the invention, when the resist 20 is to be patterned, a whole region in the opening portion of the via opening portion 16 is not exposed but a part of the opening portion is maintained to be covered with the resist 20. More specifically, only a necessary part for a via connection in a region in the via opening portion 16 to which the wiring 12 is exposed is exposed and the other parts of the via opening portion 16 are maintained to be covered with the resist 20.

In FIG. 5F, then, copper electrolytic plating is carried out by utilizing the plating resist 20. Consequently, a predetermined part of the opening portion of the via opening portion 16 is filled with copper by electrolytic plating so that a via wiring 30 for an interlayer connection is formed, and furthermore, a predetermined wiring pattern is formed on the insulating resin layer 14 to be the upper layer. In FIG. 5G, thereafter, the plating resist 20 is removed, and furthermore, the plating seed layer 18 present under the plating resist 20 thus removed is removed by etching.

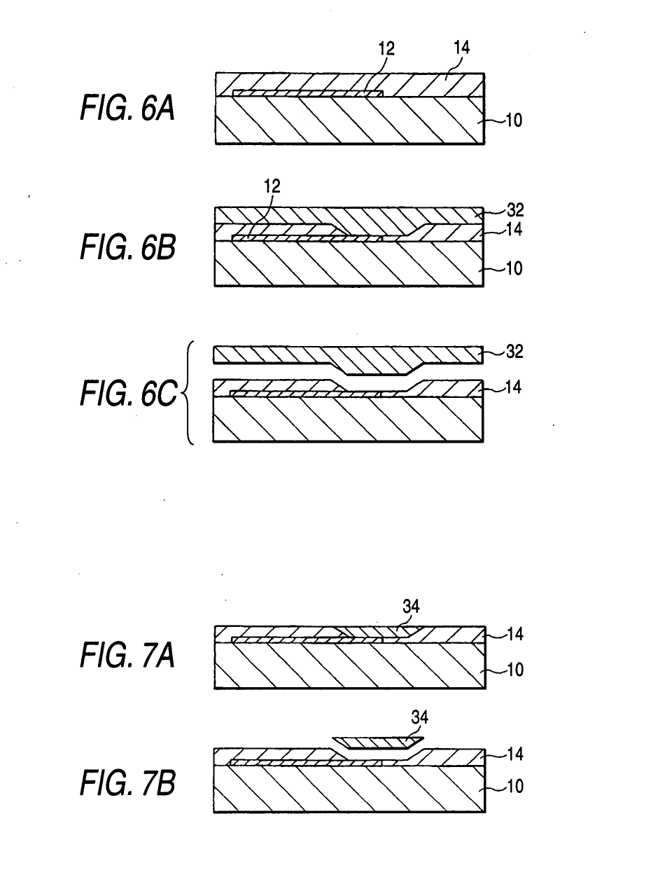

FIGS. 6 and 7 show a method of forming the opening portion of the via opening portion 16 by a stamping press or die embedding. The case in which the stamping press is used is shown in FIG. 6. In FIG. 6A, the lower wiring 12 is formed by patterning on the resin substrate 10 to be a lower layer and the insulating resin layer 14 is then formed thereon. In the case in which a thermoplastic resin is used as the insulating resin substrate 14, the insulating resin layer 14 is formed on the resin substrate 10 to be the lower layer and heating is then carried out to reduce a resin viscosity, and a stamping tool 32 having a predetermined tapered convex portion is pressed against the insulating resin layer 14 in FIG. 6B and cooling is thereafter carried out so that the opening portion of the via opening portion 16 can be formed. After the opening portion is formed, the stamping tool is released as shown in FIG. 6C.

In the case in which a thermosetting resin is used as the insulating resin layer 14, moreover, the insulating resin layer 14 which has not been completely cured is formed on the resin substrate 10 to be the lower layer and the heating is then carried out, and the stamping tool 32 having the predetermined tapered convex portion is pressed against the insulating resin layer 14 in FIG. 6B before the resin viscosity is reduced and the curing is carried out. Thus, the opening portion of the via opening portion 16 can be formed. After the heating is maintained and the insulating resin 14 is completely cured so that the opening portion is formed, the stamping tool is released as shown in FIG. 6C.

In the case in which a die embedding method is used, a die 34 is embedded in an opening portion forming place on the insulating resin layer 14 and the opening portion of the via opening portion 16 is thus formed as shown in FIG. 7A, and the embedding die 34 is released as shown in FIG. 7B.

Also in any via hole method such as the laser beam processing, the photoprocess or the stamping press, a tapered opening portion having an inclined wall surface is formed on the insulating resin layer 14 and a part of the via opening portion 16 to be the lower layer is disposed to be exposed in the opening portion.

As described above, according to the invention, in the case in which an electrical connection between the upper and lower layers is carried out through the opening portion of the via opening portion 16 provided on the insulating resin layer of a wiring substrate constituting a multilayer wiring substrate, the electrolytic plating is carried out in a state in which a part of the wall surfaces of the via opening portion 16 is covered with the resist 20 in such a manner that all of the wall surfaces of the via opening portion 16 are not covered with the via wiring 30 constituted by an electrolytic copper plated layer. In a state in which a part of the wall surfaces of the via opening portion 16 is exactly exposed, consequently, an electrical connection between the upper and lower layers is carried out through the via wiring 30. In the electrical connection between the layers of each wiring substrate of the multilayer wiring substrate, accordingly, it is not necessary to enlarge a wiring pitch and to increase a wiring length and a wiring width in order to maintain the via forming portion. Consequently, a size of a product does not need to be increased.

Next, description will be given to various embodiments for carrying out the electrical connection between the layers through the opening portion of the via opening portion 16 in the multilayer wiring substrate according to the invention.

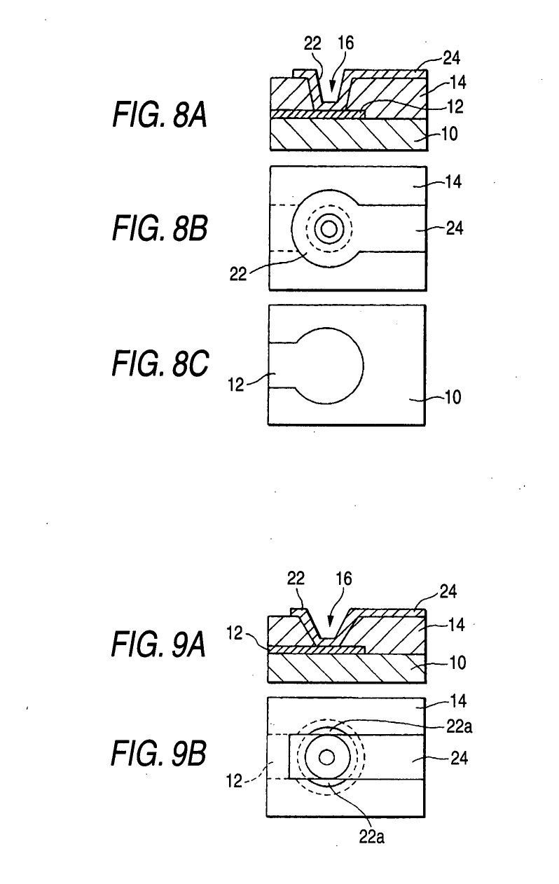

FIG. 8 shows an interlayer connecting portion according to the related art, and FIG. 8A is a vertical sectional view, FIG. 8B is a top view showing an upper wiring and FIG. 8C shows a lower wiring. In these drawings, 10 denotes an insulating resin layer to be a lower layer, 12 denotes a wiring portion of the lower layer, 14 denotes an insulating resin layer to be an upper layer, 16 denotes a via opening portion, 22 denotes a via connecting portion formed by a conductive material, and 24 denotes a wiring portion of the upper layer. As shown in the drawings, in the related art, both of the upper and lower layers have connection wiring portions provided over the whole wall surface of the opening portion of the via opening portion 16 in order to ensure a connecting reliability.

FIG. 9 shows an interlayer connecting portion corresponding to FIG. 8, and FIG. 9A is a longitudinal sectional view and FIG. 9B is a top view showing an upper wiring. In the embodiment, a via connecting portion 22 is not formed by a conductive material over a whole region of a wall surface of a via opening portion 16 but the conductive material is formed on an extension of an upper wiring 24 at the wall surface and bottom face of the via opening portion 16. In a partial region, that is, regions 22a and 22a provided out of the extension of the upper wiring 24 toward both sides, the conductive material is not formed but an interlayer connection to a lower wiring 12 is carried out. In a wiring layer to be an upper layer, accordingly, a wiring width in the connecting portion 22 is not greater than a wiring width in a rear part of the connecting portion but is almost equal thereto.

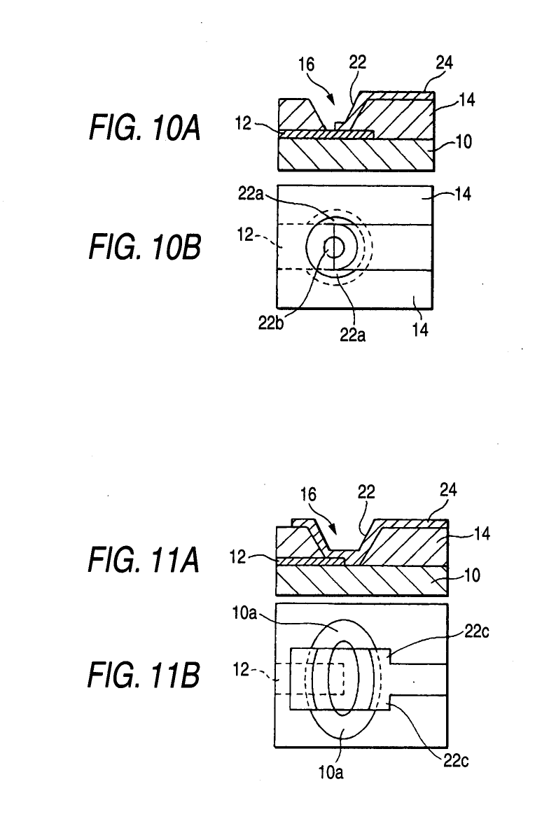

Similarly, FIG. 10 shows an interlayer connecting portion corresponding to FIG. 8, and FIG. 10A is a longitudinal sectional view and FIG. 10B is a top view showing an upper wiring. In the embodiment, in the same manner as in FIG. 9, a via connecting portion 22 is not formed by a conductive material over a whole region of a wall surface of a via opening portion 16 but the conductive material is formed on only an extension of an upper wiring 24 at the wall surface of the via opening portion 16, and the conductive material is not formed in a partial region, that is, regions 22a and 22a provided out of the extension of the upper wiring 24 toward both sides. Furthermore, the via connecting portion 22 formed by the conductive material is provided up to the middle of the bottom face of the via opening portion 16 and the conductive material is not formed in a forward region 22b of the bottom face of the via opening portion 16. Accordingly, an electrical connection to a lower wiring 12 through the via connecting portion 22 is carried out in rear and central regions of the bottom face of the via opening portion 16.

FIG. 11 shows an interlayer connecting portion according to another embodiment, and FIG. 11A is a longitudinal sectional view and FIG. 11B is a top view showing an upper wiring. In the embodiment, an opening section of a via opening portion 16 takes an elliptical shape and a comparatively large opening region is provided in an orthogonal direction to a direction in which wirings 12 and 24 of lower and upper layers are extended. A via connecting portion 22 formed by the conductive material covers the via opening portion 16 in the direction in which the wiring is extended and includes portions 22c and 22c having widths increased. However, the via connecting portion 22 is not formed over a whole region of a bottom face or a wall surface of the via opening portion 16. In portions 10a and 10a on both sides in a direction of a major axis in an elliptical shape of the via opening portion 16, the conductive material is not formed but an insulating resin layer to be a lower layer is exposed. The wiring 12 of the lower layer has the same width along its longitudinal direction.

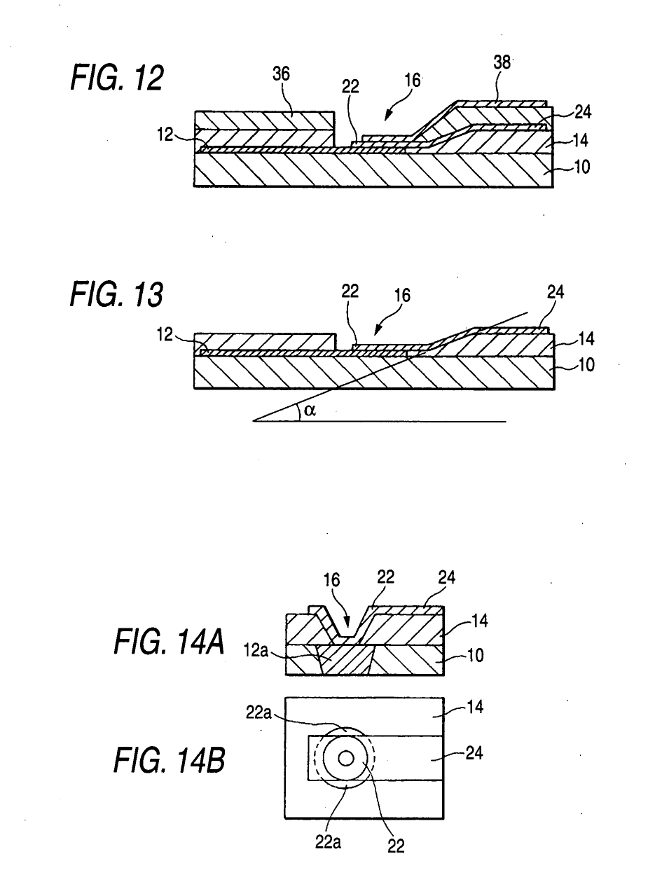

FIG. 12 is a longitudinal sectional view showing a further embodiment in which an interlayer connection is carried out over a plurality of layers of a multilayer wiring substrate. In the embodiment, referring to the step described with reference to FIG. 5, wirings 22 and 24 of a first layer are connected to a wiring 12 of a lower layer and an insulating resin layer 36 to be a second layer is then formed thereon, a via opening portion is formed again in the same position as an original via opening portion 16, a wiring 38 of a second layer is bonded to a wiring via connecting portion of the first layer, and the wiring 12 of the lower layer, the wiring 22 of the first layer and the wiring 38 of the second layer are overlaid sequentially. Consequently, an electrical connection among the three layers is carried out. Also in the case in which the electrical bonding is carried out in the via connecting portion over at least three wiring layers, thus, a conductive material is not formed over a whole wall surface of the via opening portion but a partial region of the via opening portion is not utilized as a bonding portion and the via opening portion is maintained to be exposed.

FIG. 13 shows an inclination angle of a tapered wall surface of a via opening portion 16 in a portion through which wirings 22 and 24 of a first layer pass in the case in which the wirings 22 and 24 of the upper layer are connected to a wiring 12 of a lower layer to manufacture a multilayer wiring substrate through the step described with reference to FIG. 5. An inclination angle a is set to be smaller than 90 degrees and the wirings 22 and 24 are bent at an obtuse angle in the via opening portion 16, thereby carrying out a connection between the layers. Consequently, the wiring can easily be formed on the wall surface of the via opening portion, and furthermore, the wirings 22 and 24 can be extended smoothly. Consequently, it is possible to prevent an excessively intensive stress and an electrically local change from being received.

FIG. 14 shows an interlayer connecting portion according to a further embodiment, and FIG. 14A is a longitudinal sectional view and FIG. 14B is a top view showing an upper wiring. In the embodiment, a via hole of an insulating resin layer 10 to be a lower layer is filled with a conductive material to constitute a filled via 12a. In the case in which a wiring layer (not shown) to be a lower layer is further present, accordingly, an electrical connection to the wiring can be carried out or the filled via 12a can also be used as an external connecting terminal. The other structures are the same as those in the embodiment shown in FIG. 9, and a via connecting portion 22 is not formed by a conductive material over a whole region of a wall surface of a via opening portion 16 of an insulating resin layer 14 to be an upper layer but the conductive material is formed on only an extension of an upper wiring 24 of the wall surface of the via opening portion 16.

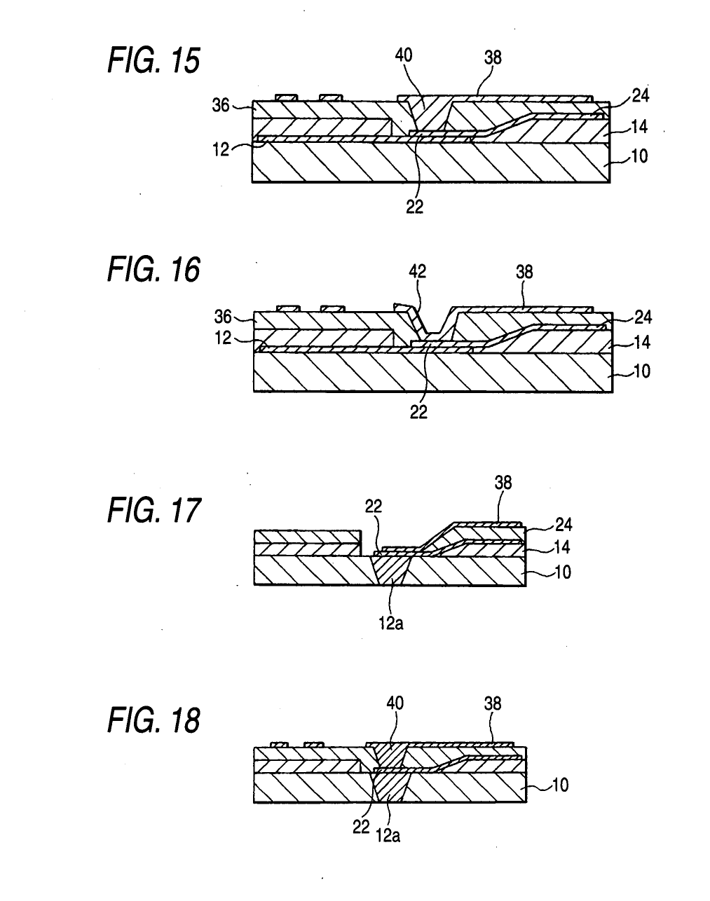

FIGS. 15 and 16 are longitudinal sectional views showing further embodiments of the interlayer connecting portion over a plurality of layers shown in FIG. 12. In the embodiment of FIG. 15, an interlayer connection is carried out through a filled via 40 obtained by completely filling a via opening portion with a conductive material in order to bond a wiring 38 of a second layer to a bonding portion of a wiring 22 of a first layer and a wiring 12 of a lower layer. On the other hand, in the embodiment of FIG. 16, an interlayer connection is carried out through an unfilled via 42 obtained by partially filling a via opening portion with a conductive material in order to bond a wiring 38 of a second layer to a bonding portion of a wiring 22 of a first layer and a wiring 12 of a lower layer.

In FIG. 17, a filled via 12a is obtained by completely filling the via hole of the insulating resin layer 10 to be the lower layer with a conductive material in the embodiment of FIG. 12. In an embodiment of FIG. 18, similarly, a filled via 12a is obtained by completely filling the via hole of the insulating resin layer 10 to be the lower layer with a conductive material and an interlayer connection is carried out through a filled via 40 obtained by completely filling a via opening portion with a conductive material through electrolytic plating in order to bond a wiring 38 of a second layer to a bonding portion of a wiring 22 of a first layer and a wiring 12 of a lower layer in the same manner as in the embodiment of FIG. 15.

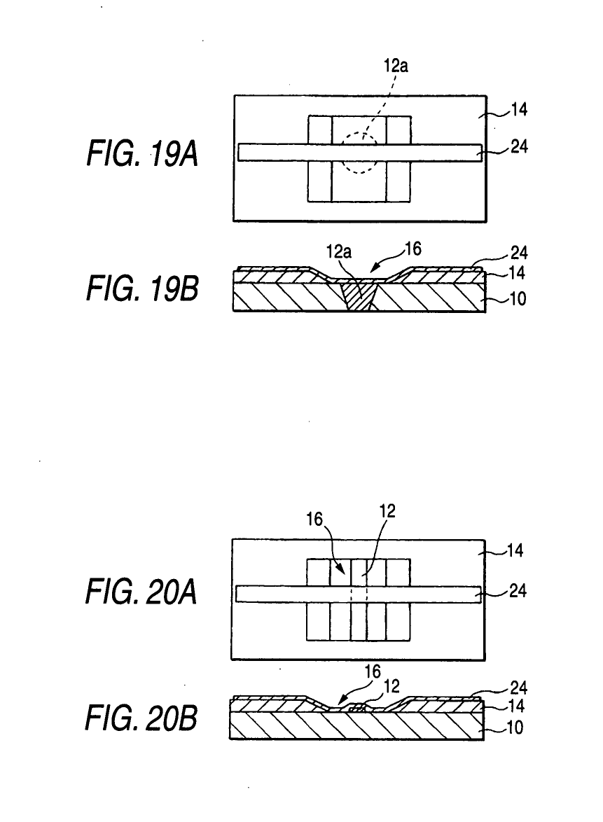

FIG. 19 shows a further embodiment, and FIG. 19A is a top view showing an upper wiring and FIG. 19B is a longitudinal sectional view. In the embodiment, a filled via 12a is obtained by completely filling a via hole of an insulating resin layer 10 to be a lower layer with a conductive material, and a wiring 24 of an upper layer is bonded to the filled via 12a in a via opening portion 16, and furthermore, is extended straight in a forward direction over an insulating resin layer 14 to be an upper layer in an exact width. In the embodiment, the wiring 24 of the upper layer is extended over an inclined portion taking a shape of a taper in the via opening portion 16 before and after a bonding portion to the filled via 12a.

FIG. 20 also shows a further embodiment, and FIG. 20A is a top view showing an upper wiring and FIG. 20B is a longitudinal sectional view. In the embodiment, a wiring 12 provided on an insulating resin layer 10 to be a lower layer and a wiring 24 provided on an insulating resin layer 14 to be an upper layer are extended orthogonally to each other while maintaining exact widths, and both of the wirings 12 and 24 cross each other at a right angle and are thus bonded to each other in a via opening portion 16. Also in the embodiment, the wiring 24 of the upper layer is extended over an inclined portion taking a shape of a taper in the via opening portion 16 before and after a bonding portion to a filled via 12a.

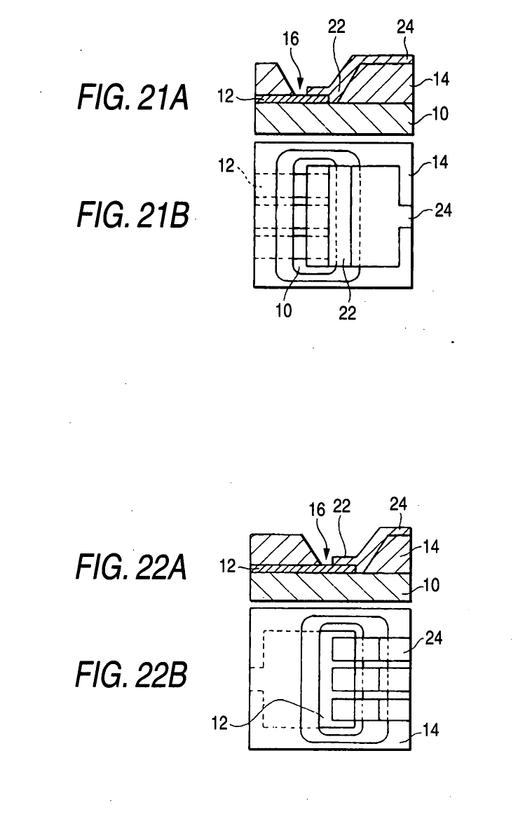

FIGS. 21 to 25 show a structure in which a plurality of wirings is connected to a via opening portion 16 through an interlayer connection. In an embodiment of FIG. 21, FIG. 21A is a longitudinal sectional view and FIG. 21B is a top view in which a single wiring 24 of an upper layer is connected to a plurality of wirings 12 of lower layers in one via opening portion 16. Also in the embodiment, the wiring 24 of the upper layer has a width increased so that a via connecting portion 22 is formed. However, the via connecting portion 22 does not cover a whole region of the via opening portion 16 but a conductive material is not provided on both sides thereof. Although a connecting portion to a plurality of lower wirings 12 arranged in parallel at an interval is maintained, the via connecting portion 22 is not extended to a forward part thereof but a region in which an insulating resin layer 10 to be a lower layer is exposed is present in an inner region of the via opening portion 16.

In an embodiment of FIG. 22, FIG. 22A is a longitudinal sectional view and FIG. 22B is a top view. Contrary to the previous embodiments, a plurality of upper wirings 24 arranged in parallel at an interval is connected to a single lower wiring 12 in one via opening portion 16. In the embodiment, although the lower wiring 12 has a width increased in the via opening portion 16, a whole region of the via opening portion 16 is not covered but a region in which a conductive material is not provided is present on both sides thereof. Although a connecting portion to the upper wiring 24 is maintained, moreover, the lower wiring 12 is not extended to a forward part thereof and a region in which an insulating resin layer 10 to be a lower layer is exposed is present in an inner region of the via opening portion 16. In a portion of an inner part of the via opening portion 16 in which the width of the lower wiring 12 is increased, a plurality of upper wirings 24 disposed in parallel is bonded.

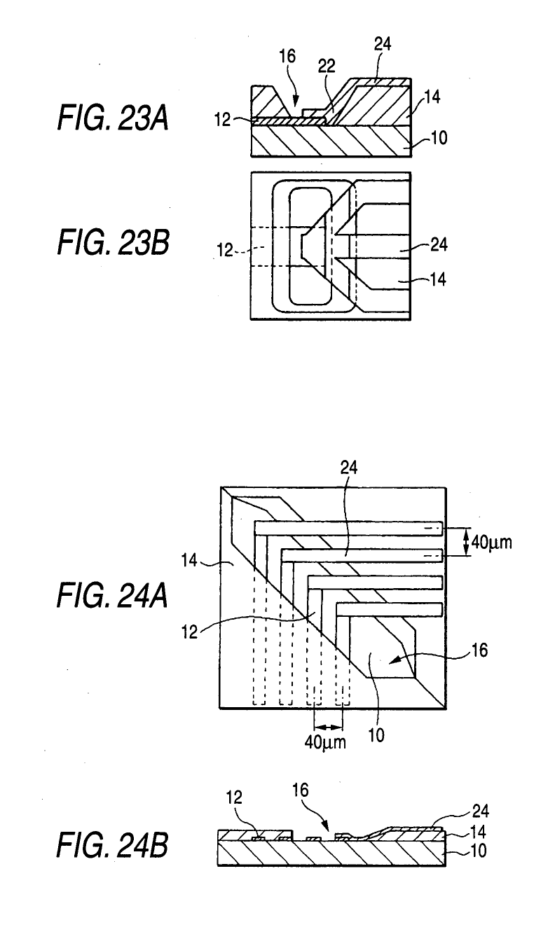

In an embodiment of FIG. 23, FIG. 23A is a longitudinal sectional view and FIG. 23B is a top view. In the same manner as in the embodiment of FIG. 22, a plurality of upper wirings 24 is connected to a single lower wiring 12 in one via opening portion 16. In the embodiment, however, the lower wiring 12 is extended in an exact width up to an inner part of the via opening portion 16 and a plurality of upper wirings 24 having an equal width is bonded to converge on one point of the lower wiring. The upper wiring 24 is extended radially from the bonding point to an upper surface of an insulating resin layer 14 to be an upper layer. Also in the embodiment, it is a matter of course that a region in which an insulating resin layer 10 to be a lower layer is exposed is present in a bottom part of the via opening portion 16.

In an embodiment of FIG. 24, FIG. 24A is a top view and FIG. 24B is a longitudinal sectional view. In the embodiment, a plurality of lower wirings 12 having an equal width and disposed in parallel at an interval and a plurality of upper wirings 24 having an equal width and disposed in parallel at an interval in the same manner are connected to each other in one via opening portion 16. The lower wiring 12 and the upper wiring 24 are extended in a perpendicular direction with the equal widths maintained. Moreover, the via opening portion 16 is extended in a direction at an angle of 45 degrees with respect to the lower wiring 12 and the upper wiring 24 and respective bonding points of the lower wirings 12 and the upper wirings 24 are sequentially arranged in a direction at an angle of 45 degrees with respect to the respective wirings along an inner part of the via opening portion 16. In the embodiment, the upper wiring 24 for carrying out an interlayer connection is extended along an inclined wall in the via opening portion 16. It is a matter of course that a portion in which an insulating resin layer 10 to be a lower layer is exposed is present in the via opening portion 16.

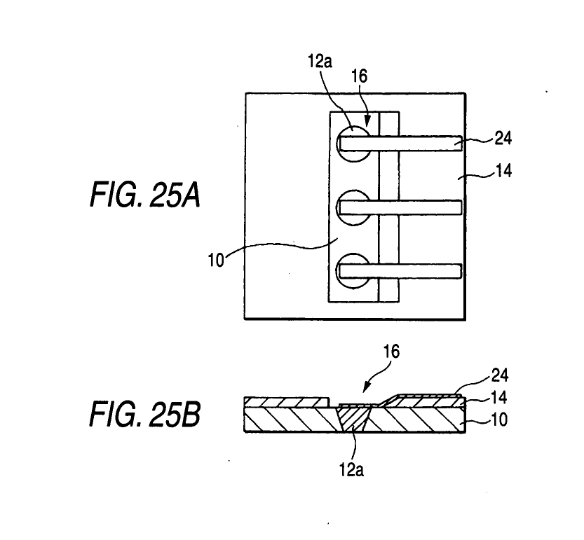

In an embodiment of FIG. 25, FIG. 25A is a top view and FIG. 25B is a longitudinal sectional view in which a plurality of upper wirings 24 having an equal width is connected to a plurality of filled vias 12a penetrating through an insulating resin layer 10 to be a lower layer and disposed at an interval respectively in one via opening portion 16. The upper wirings 24 are extended in a parallel direction at an interval with the equal width maintained. The via opening portion 16 is extended in a perpendicular direction to the upper wiring 24, and respective bonding points of a plurality of filled vias 12a to be lower wirings and a plurality of upper wirings 24 are sequentially arranged in a perpendicular direction to a direction in which the upper wirings 24 are extended along the via opening portion 16. Also in the embodiment, the upper wiring 24 for carrying out an interlayer connection is extended along an inclined wall in the via opening portion 16. It is a matter of course that a portion in which the insulating resin layer 10 to be the lower layer is exposed is present in the via opening portion 16.

While each of the embodiments of the invention has been described above with reference to the accompanying drawings, the invention is not restricted to the embodiments but various configurations, changes and modifications can be made without departing from the spirit and scope of the invention.

As described above, according to the invention, in the case in which the electrical connection between the upper and lower layers is to be carried out through the opening portion of the via opening portion 16 provided on the insulating resin layer of the wiring substrate constituting the multilayer wiring substrate, the electrical connection between the upper and lower layers is performed through a conductive material in a state in which a part of the wall surfaces of the opening portion is exactly exposed in such a manner that all of the wall surfaces of the opening portion are not covered with the conductive material. In the electrical connection between the layers of each of the wiring substrates of the multilayer wiring substrate, accordingly, it is not necessary to enlarge a wiring pitch and to increase a wiring length and a wiring width in order to maintain the via forming portion. Therefore, a space for the electrical connection between the layers of the multilayer wiring substrate can be reduced as greatly as possible. Thus, it is possible to prevent a size of a product from being increased.

What is claimed is:

1. A method of connecting a multilayer wiring substrate comprising step of:
performing an electrical connection between upper and lower layers, through an opening portion, which is provided on an insulating layer of each wiring substrate constituting the multilayer wiring substrate and is covered with a conductive material while a part of wall surfaces of the opening portion is exposed from the conductive material.

2. The method of connecting a multilayer wiring substrate according to claim 1, wherein either a wiring layer to be the upper layer and a wiring layer to be the lower layer has a wiring width in a connecting portion which is not greater than a wiring width before and after the connecting portion but is almost equal thereto.

3. The method of connecting a multilayer wiring substrate according to claim 1, wherein a plurality of wiring connecting portions between the upper and lower layers is formed in one opening portion.

4. The method of connecting a multilayer wiring substrate according to claim 1, wherein a connecting portion of a wiring layer to be the lower layer is a via filled with a conductive material.

5. The method of connecting a multilayer wiring substrate according to claim 1, wherein a connecting portion of a wiring layer to be the upper layer is a via in which a conductive material is formed on a part of the wall surfaces of the opening portion of the insulating layer.

6. The method of connecting a multilayer wiring substrate according to claim 1, wherein a wiring layer to be the upper layer is electrically connected to a connecting portion of a wiring layer to be the lower layer, and a wiring layer to be a further upper layer is electrically connected to the same connecting portion.

7. The method of connecting a multilayer wiring substrate according to claim 1, wherein the opening portion provided on the insulating layer is inclined to a plane of a connecting portion and an inclination angle is smaller than 90 degrees.

8. A multilayer wiring substrate having a structure in which an upper wiring layer and a lower wiring layer are electrically connected to each other through an opening portion, which is provided on an insulating layer of each wiring substrate constituting the multilayer wiring substrate and is covered with a conductive material while a part of wall surfaces of the opening portion is exposed from the conductive material.
